(19) United States
(12) Patent Application Publication
(10) Pub. No.: US 2012/0222727 A1
(43) Pub. Date: Sep. 6, 2012

(54) Module Arrangement Consisting of Solar Modules

(75) Inventor: Wadim Salzer, Bielefeld (DE)

(73) Assignee: SCHUECO International KG, Bielefeld (DE)

(21) Appl. No.: 13/395,048

(22) PCT Filed: Sep. 7, 2010
(86) PCT No.: PCT/EP2010/063117

§ 371 Date: Mar. 8, 2012

(30) Foreign Application Priority Data
Sep. 10, 2009 (DE) 20 2009 011 880.0
Sep. 10, 2009 (DE) 20 2009 012 226.3

(51) Int. Cl. H01L 31/048

(52) U.S. Cl. 136/251

(57) ABSTRACT

The invention relates to a module arrangement having the following: double module arrangements, each consisting of two solar modules oriented at an angle to each other; wherein the two solar modules (1) of the individual double module arrangements are coupled to each other at least in the region of their opposing upper edges; wherein the two solar modules (1) of each double module arrangement are coupled to each other via one or more connectors (6); wherein the connector (6) for connecting the two modules of a double module arrangement is formed at an angle and has two limbs (11,12) which form an angle α, said angle being between 95° and 175°; wherein one or more profiles (5) are arranged under the solar modules, and in particular under glass-glass thin film laminate modules, said profiles having one or more chambers, wherein adjacent double module arrangements are connected to each other via at least one or more coupling devices, said coupling devices having anti-slip devices (4). The one or more chambers of the profile or profiles (5) is or are designed to secure the connector (6, 7) by receiving said connector (6, 7).

### CROSS-REFERENCE TO RELATED APPLICATIONS

This application contains subject matter related to U.S. application Ser. No. ______, entitled “A Module Arrangement Consisting of Solar Modules,” filed on even date herewith.

### BACKGROUND AND SUMMARY OF THE INVENTION

The invention relates to an arrangement consisting of solar modules on surfaces, in particular roofs.

Generic module arrangements are known from DE 100 47 400 C2 and from DE 20 2008 007 549 U1. These documents each disclose solar module arrangements which are arranged by means of mounting devices in a so-called fold arrangement on a roof in such a manner that they form a zigzag arrangement in a side view. This type of zigzag arrangement makes it possible to completely or almost completely cover a roof surface with solar modules, which optimizes energy recovery in particular when the fold or zigzag arrangement is aligned in an east-west direction.

A disadvantage in the two known structures and, quite generally, in the prior art—where DE 10 2007 000 697 A1, DE 295 03 315 U1 and DE 199 34 059 A1 are also mentioned for the technological background—is the high material input in view of the mounting devices or substructures. In particular, the known mounting devices have a relatively large number of components and structural elements.

Against this background, starting from the generic prior art, it is the object of the invention to simplify the generic arrangement in regard to its substructure and in regard to the mounting device.

This object is achieved by a module arrangement, comprising double module arrangements each consisting of two solar modules oriented at an angle to each other; wherein the two solar modules of the individual double module arrangements are coupled to each other at least in the region of their opposing upper edges; wherein the two solar modules of each double module arrangement are coupled to each other via one or more connectors; wherein the connector for connecting the two modules of a double module arrangement is formed at an angle and has two legs which form an angle α, said angle being between 95° and 175°; wherein one or more profiles are arranged under the solar modules, and in particular under glass-glass thin film laminate modules, said profiles having one or more chambers; wherein adjacent double module arrangements are connected to each other via at least one or more coupling devices, said coupling devices having anti-slip devices; and wherein the one or more chambers of the profile or profiles is/are designed to secure the connector by receiving said connector.

The term “solar modules” is not to be limiting and includes solar elements of the most diverse type which form a type of pre-mounted module and which serve to produce energy in the form of power and heat. The type of mounting (arrangement) according to the invention is therefore suitable both for photovoltaic modules and also for thermal energy collectors and can preferably be arranged on flat roofs or sloping roofs, but also on any free surfaces. Further advantages are the aerodynamic arrangement of the solar modules whereby weighting down or anchorings are superfluous.

According to the invention, it is initially provided that neighboring module arrangements—which in cooperation then form a type of zigzag arrangement—are interconnected via coupling devices having an anti-slip function.

The anti-slip devices counteract any slipping on the subsurface. They are preferably supported on a subsurface without a fastener and are preferably configured in such a manner that they have a relatively high adhesive friction with the subsurface. Weighting-down weights are therefore generally not required.

Anti-slip devices for placing solar modules on a flat subsurface are certainly known per se, thus from DE 10 2007 000 697 A1. In this document, however, it was not recognized that it is easily possible to use such anti-slip devices directly for coupling neighboring double solar module arrangements. An aerodynamically closed and substantially “closed” surface can be created by this means, which makes weights or the like for weighing down the solar module arrangements superfluous. In addition, the problem of erecting double solar module arrangements which are generally relatively extensive and heavy does not arise since only solar module arrangements each having a solar module aligned towards a sky direction are disclosed in the document.

It is particularly simple that the two solar modules of each double module arrangement are preferably only intercoupled via one or a plurality of connectors, in particular in the area of their “upper” edge. The “lower” edges of each double module arrangement facing away from one another are not interconnected via a profile.

It is expedient and constructively simple if the anti-slip devices are coupled to one or more double module arrangements via at least one connector.

It is furthermore particularly advantageous if the anti-slip devices also take on the function of transferring the load of the double solar module arrangements into the subsurface.

The anti-slip devices are particularly preferably configured in such a manner that the distance between the lower edges of neighboring double module arrangements is 50 to 500 mm, preferably 300 mm, which in turn simplifies maintenance.

The anti-slip devices are furthermore preferably configured in such a manner that the intermediate space between neighboring double module arrangements can be walked upon.

According to a further preferred variant, at least one profile, which comprises one or more chambers which is/are designed to receive the connectors, is arranged below the solar module, in particular below glass-glass-thin film laminate modules. The profile in particular makes it possible to simply fix the connectors on the solar module. Alternatively, according to a less preferred embodiment of the invention, it is also feasible to fix the connectors directly on the solar module without the profile, e.g., in a glass region in fastening holes or the like.

Preferably, the two solar modules of the at least one double solar module arrangement are merely coupled to one another in the area of their mutually facing edges. As a result, the expensive support profiles required according to the prior art are omitted, in particular the so-called lower support profiles, cross members, or ground struts. This results in cost savings and a simplified assembly.

Some advantages of the invention are as follows.

A mounting arrangement is provided which, in a preferred configuration, manages without additional ballast and/or a fastening on the subsurface.

The mounting arrangement is particularly suitable for unframed solar elements (laminates, preferably thin-film laminates made of double safety glass).

A separate substructure fastened to the building is not required since the module carries and supports itself. Wind deflectors can also be dispensed with.

An arrangement having a very high surface proportion of solar elements is created, which is distinguished by a controlled unobstructed water drainage, good accessibility for maintenance access and simple and safe cable laying in the maintenance access.

The anti-slip device used is also particularly advantageous in regard to observing row spacings, which serves as a compression member and also for receiving horizontal shear forces, e.g., through wind, and for connecting at least two lower solar element edges.

The anti-slip device is preferably configured as a support plate for load transfer.

The connecting angles preferably consist of stainless steel and are clamped in profile grooves and, specifically, in profile grooves preferably of a profile of solar modules configured as laminates with a profile which is also designated as a so-called backrail (frameless elements).

### BRIEF DESCRIPTION OF THE DRAWINGS

The invention is explained in detail hereinafter with reference to an exemplary embodiment with reference to the drawings. In the figures:

FIG. 1 shows a perspective view of an arrangement of solar modules formed from a module arrangement according to the invention on a flat roof;

FIG. 2 shows a side view of a row of solar modules;

FIGS. 3 and 4, respectively, show a side view of a multi-row solar module arrangement and a plan view of this solar module arrangement;

FIG. 5 shows a sectional view of a profile;

FIG. 6 shows a sectional view of a connector;

FIG. 7 shows a sectional view of another connector;

FIG. 8A,B show a side view and a perspective view respectively, of an anti-slip device;

FIG. 9 shows a perspective view of another anti-slip device;

FIG. 10a,b show a front view and a side view, respectively, of a two-row solar module arrangement;

FIG. 11a,b show a side view of a connector and a plan view of this connector, respectively;

FIG. 12a,b show a side view of another connector and a plan view of this connector, respectively; and

FIG. 13 shows a view of a tension cable.

### DETAILED DESCRIPTION OF THE DRAWINGS

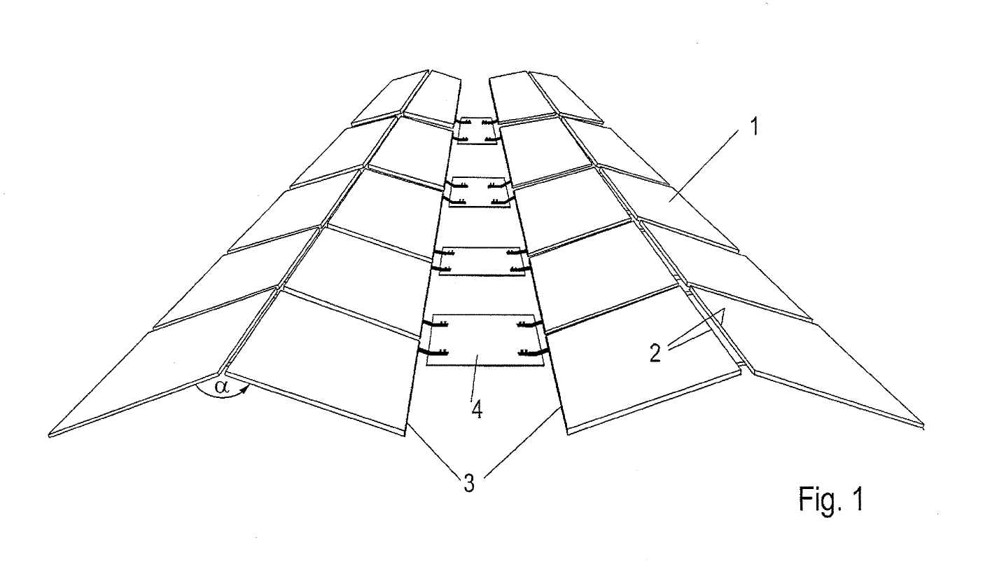

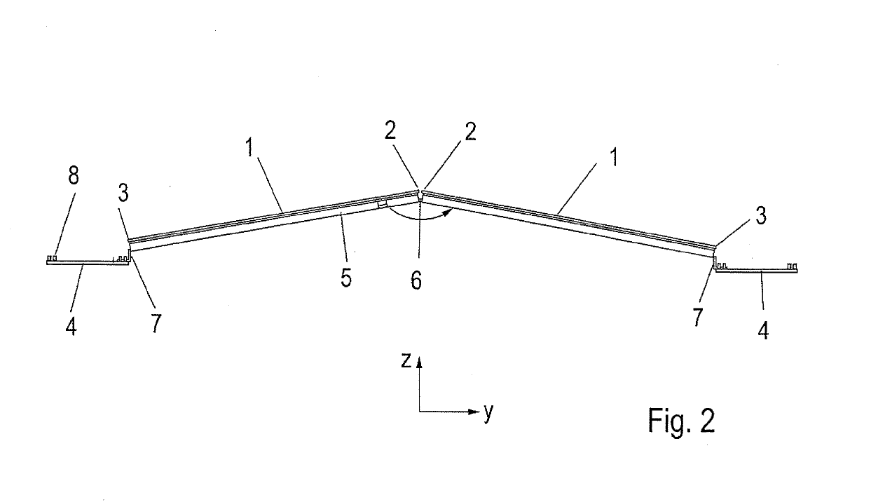

FIG. 1 shows an exemplary module arrangement according to the invention which has at least two—as in FIG. 2—or a plurality of solar modules 1.

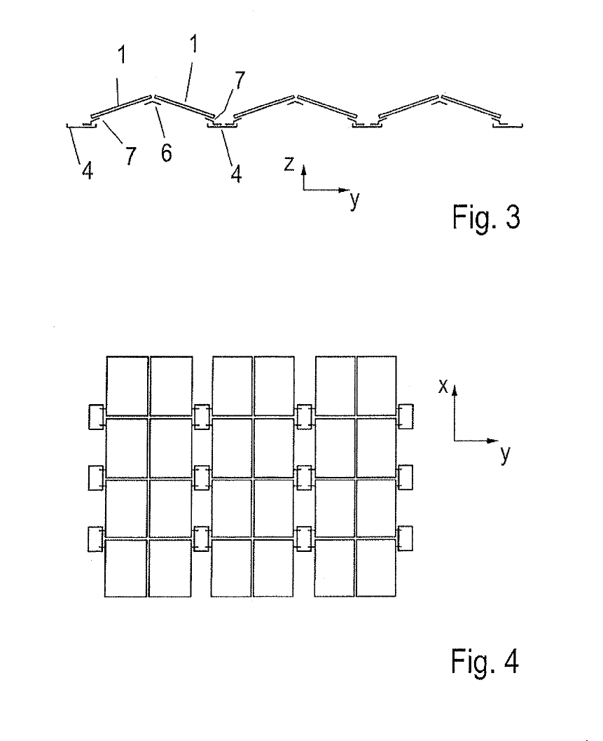

To simplify the discussion, FIGS. 2 and 3 are provided with a Cartesian coordinate system. Here, the coordinates X and Y each describe the coordinates of the subsurface or floor space for the solar module, which is assumed to be flat here, and the additional coordinate Z describes the coordinate perpendicular hereto. In the case of a flat roof or another flat subsurface, the X and Y coordinates characterize this surface accordingly whereas the Z coordinate in each case is the vertical coordinate. The following designations such as “top” or “bottom” are explained from this alignment which, however, are not to be understood as restrictive especially as the invention is suitable for obliquely aligned subsurface areas such as, for example, a sloping roof.

It should be noted that the term “solar module” is used continuously hereinafter but that this should be understood to be representative for modules of different types such as solar cell modules or thermal energy modules.

The solar modules 1 in FIG. 1 preferably have a relatively flat, rectangular basic shape. In each case, two of the solar modules 1 are coupled to one another by way of connectors 6, 7 which are shown by way of example in FIGS. 6 and 7, in such a manner that in each case two of the solar modules abut against one another in pairs in the area of one of their outer edges 3 and thereby enclose an angle α which is preferably—but not necessarily—greater than 90°.

Preferably, a plurality of such double module arrangements are arranged in a row (X direction) one behind the other. In addition, on a subsurface such as a roof, it is also possible to arrange a plurality of these rows of double modules next to one another (Y direction) in order to cover a roof surface or the like as desired, in particular also all-over, with solar modules.

The designation of a zigzag arrangement or fold arrangement is obtained from this type of arrangement.

The substructure is thereby appreciably simplified compared with the prior art.

In the mounting arrangement according to the invention, the double module arrangements are in each case interconnected at facing vertical upper edges 2 in the erected position but not in the area of the lower edges 3 which point away from one another.

Instead, in the mounted position a connection is made through the subsurface itself. An additional connection to the subsurface in the area of the lower edges facing away from one another is, however, not provided or is eliminated within a double module arrangement.

Compared with the prior art as known from DE 20 2008 007 549 U1, a double module arrangement having a significantly simplified structure is provided because the intermediate supports or profiles provided there, which interconnect the lower edges of each double profile arrangement facing away from one another can be dispensed with. Preferably, no additional supporting strut is provided in the area between the connectors 6, 7 and the lower edges 3.

Neighboring, adjoining double module arrangements are furthermore interconnected in the area of the adjoining (here lower) edges 3 via coupling devices or elements. These coupling elements preferably achieve such a spaced-apart connection of the lower edges 3 of neighboring double module arrangements that good accessibility to the double module arrangements is ensured for mounting purposes or maintenance work.

The distance between the lower edges 3 of the neighboring double module arrangements is preferably 50 to 500 mm, and preferably 300 mm. The distance of the lower edges 3 is preferably predefined by one or more coupling devices.

Preferred embodiments of these coupling elements are considered in detail hereinafter.

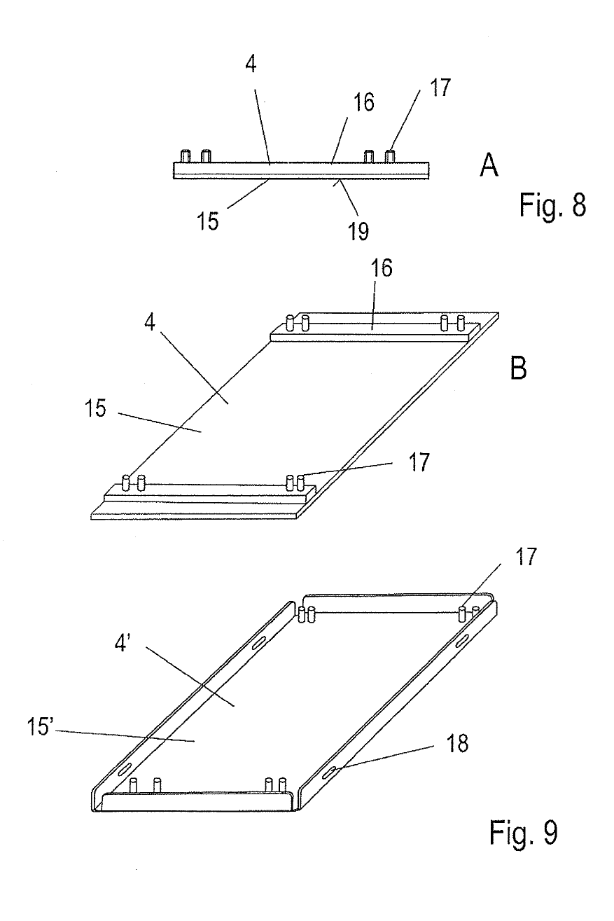

In a particularly preferred embodiment, the coupling elements or devices form integral or multipart anti-slip devices 4 (see, in particular, FIGS. 8 to 9).

The anti-slip devices 4 are preferably configured not only for achieving an anti-slip property for the double module arrangements, but they also take on the function of transferring load into the subsurface.

Preferably, at least two edges 3 of two neighboring double module arrangements, preferably four of the edges 3, are arranged or fixed on each anti-slip device 4 so that four of these solar modules can be mounted (or are mounted) per anti-slip device.

FIG. 2 shows a row of double module arrangements in a side view, where the solar modules 1 are erected at an angle to one another as described for FIG. 1. In this case, the upper edges 2 are held at a short distance. Located under the solar elements 1 (here a glass-glass-thin film laminate) are profiles 5, preferably aluminum profiles, which preferably have chambers that serve to receive the connectors or other fasteners.

At the upper edges 2, a connector 6 is inserted in the recesses of two neighboring solar modules 1. The connector 6 is—see FIG. 6—preferably configured as a one-piece angle piece and has two legs 11, 12 which enclose the angle α.

In the preferred case this angle α is 160°. As a result, the solar modules 1 have a sloping inclination or alignment of 10 degrees to a flat, for example, horizontally aligned—subsurface.

The lower edges 3 of neighboring double solar module arrangements are also aligned in a larger collector array to one another. For mounting, a connector 7 is also inserted in the profile 5 at the lower ends. The connector 7 is thus fixed on the profile 5 and therefore on the solar module. It is feasible to screw the profile 5 and the connector 7 to one another. On the side facing away from the edge 3 or the profile 5, on the other hand the connector 7 is connected to one of the anti-slip devices 4.

This anti-slip device in FIG. 8 is a very advantageous embodiment. In addition, however, other advantageous embodiments of the invention are also feasible in which the lower edges 3 of the solar elements 1 are preferably directly interconnected.

The preferred anti-slip devices 4 absorb compressive forces which are applied from the individual rows of modules due to the 10 degree arrangement. In particular, the compressive forces cancel out.

The anti-slip devices 4 are preferably provided with projecting pins 8 (see FIG. 2), preferably threaded pins, on which the connectors 7 with corresponding holes can be simply placed for easy mounting. It is then merely necessary to tightly clamp the connectors 7 using a nut screwed onto the threaded pins 8 on the anti-slip devices.

Furthermore, the anti-slip devices 4 preferably form a so-called maintenance access between neighboring double module arrangements which—as already mentioned—significantly simplifies the maintenance of the module arrangement.

FIG. 2 illustrates that no further profile mounting support system, no further cross strut within the double module arrangements, no supporting struts or the like, as described in the prior art, are required.

In a particularly preferred manner, the zigzag arrangement is merely formed by the anti-slip device 4 between neighboring double module arrangements, a connector 7 between the anti-slip device 4 and the double module arrangement, a profile 5 on which the solar module is arranged, a connector 6 between the upper edges or profiles 5 of neighboring solar modules of a double module arrangement. In turn, this can be adjoined by connectors 7, anti-slip devices 4, etc.

At the ends of larger module arrays, a tension element can be provided to absorb the compressive forces between the profiles 5 or between the connectors 7. This tension element (not shown here) can be a tension cable or a tension rod. By this means, the entire module array can be erected freely without being fastened in the subsurface or without using weights. The aerodynamic arrangement additionally prevents wind forces from being able to act under surfaces so that lifting is not possible.

FIGS. 3 and 4 once again show symbolically a solar module array which can be arbitrarily expanded and enlarged. FIG. 3 shows the fastening sequence which is important for this application, consisting of anti-slip device, connector, profile with solar module, connector, profile with solar module, connector, anti-slip device, etc.

No connecting or supporting components are located below the solar modules. Draining is possible without any problems, and likewise so is access to the modules.

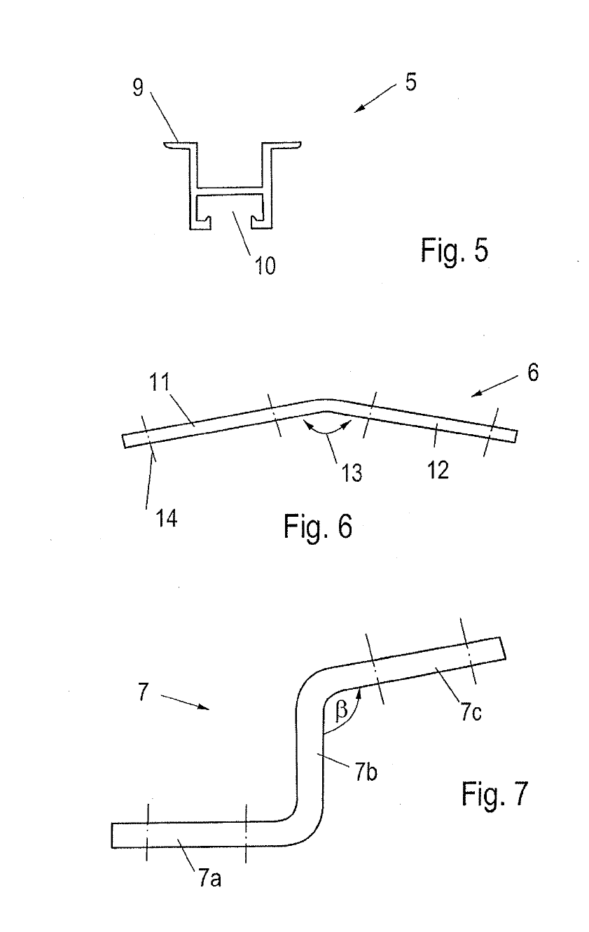

FIG. 5 is an enlarged sectional view of the profile 5, which has surfaces 9 on which the solar modules 1 (not shown here) can rest and can possibly be adhesively secured. The profile 5 furthermore has an open hollow chamber 10 in which the connector or other mounting elements can be arranged.

This profile 5 is a particularly advantageous option as a retaining element for the solar modules. Alternatively, it is feasible to fix the connectors on a module frame—if provided—or also directly on another element of the module or couple to this, thus to special fastening holes or the like.

FIG. 6 shows, in section, a connector 6 which interconnects the two solar modules of a double module arrangement in the area of the mutually facing upper edges 2.

The connector 6 has at least two legs 11 and 12, which are aligned at an angle to one another. The angle α enclosed by the legs 11, 12 preferably lies between 100° and 175°, preferably 160°.

Furthermore, the connector 6 preferably has through holes, e.g., threaded holes, on the legs 11, 12, which are provided for easy clamping of the connector 6 by use of screws in the profile 5.

FIG. 7 shows a double-bent connector 7 which is designed for fixing the lower edges 3 of the solar elements 1. The connector 7 has a supporting leg 7a, a vertical leg 7b aligned perpendicular thereto, and a further sloping leg 7c aligned at an angle β of 90°+(180°−α)/2=180°−α/2 here for fixing to the solar modules. The connector 7 preferably also has holes which are designed for connecting to the profile 5 or to the anti-slip device 4.

FIGS. 8A and B show an anti-slip device 4 which is substantially used as a connecting element between the lower edges 3 of mutually facing edges 3 of neighboring double module arrangements.

The spacing of the connection is selected to be relatively large at 300 mm and thereby has the advantage that a maintenance access is formed between the double module arrangements. This maintenance access is not absolutely necessary but is advantageously used for laying the power cable.

FIG. 8A shows a first anti-slip device 4 in a side view, where the anti-slip device here consists of a lower sheet 15 on which at least one compression rod 16 is arranged. Located on the compression rod 16, which could also be designated as spacing rod, are pins 17, preferably threaded pins, for connection of the anti-slip device to the connector 7 for the lower edges 3 of the solar elements 1.

FIG. 9 also shows an anti-slip device 4′, which for cost reasons is configured without compression rods. In order to give the sheet 15′ additional stability, in particular compressive stability, the sheet 15′ is beveled at the sides. Additional beads or sheet reinforcements are a further advantageous addition. In addition to the pins 17, the anti-slip device 4′ has oblong holes 18 in the lateral beveling, which are used for fastening cable clips and the like.

In principle, the anti-slip device 4 can have a particular configuration on its underside 19, i.e., on its side facing the roof, preferably a roughening or a friction-enhancing coating.

This can be configured as an adhesive surface, a rubberized surface, or provided with strips such as, for example, EPDM strips or configured in another way such that slippage of the elements on the subsurface is prevented.

The background for this is the fact that wind forces acting on the module array only have a relatively small lifting effect but a relatively large sliding effect, i.e., smaller forces in the vertical direction and larger forces in the horizontal direction. The anti-slip devices are therefore suitable for receiving corresponding wind loads even without additional weighting down and without fastening on the roof or subsurface. The floor area is also so large (it is preferably more than 200 mm×200 mm, in particular more than 400 mm×300 mm) so that the weight forces are well distributed. The anti-slip devices 4 then preferably only rest on a subsurface and are not fixed there with fasteners. This type of module arrangement is quite particularly cost-effective, easy to mount and nevertheless particularly secure.

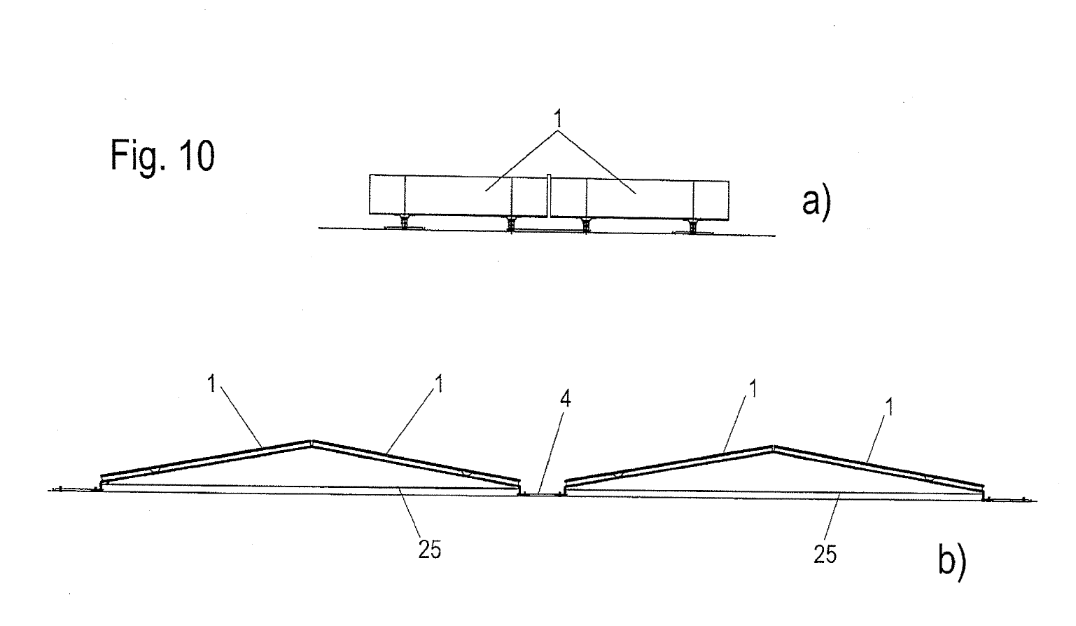

This can be seen particularly clearly from FIG. 10, which shows a front view in FIG. 10a and a side view of a two-row solar module arrangement in FIG. 10b. The arrangement is in such a manner that lifting by wind is simply and reliably prevented.

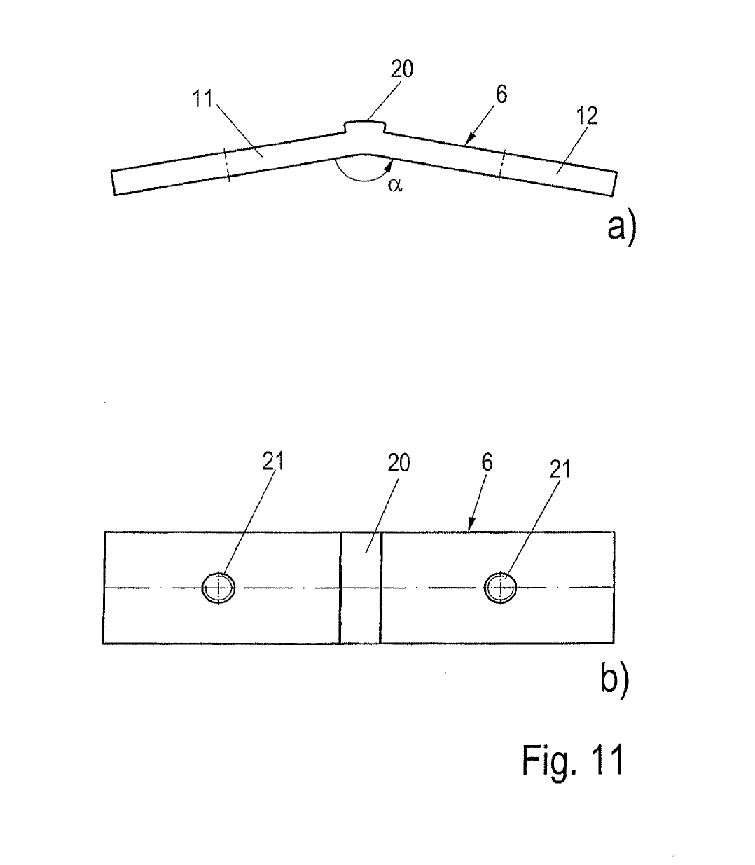

FIG. 11a, b show, respectively, a side view of a further exemplary embodiment of a connector 6 and a plan view of this connector 6 with the two legs 11, 12 and the angle α, which is 160° here. The legs 11, 12 in turn are used for inserting into the respective chambers of the profiles 5. In order to delimit the insertion path of the connector 6 into these chambers, at least one projection 20 is formed on the connector 6. It is particularly advantageous if the projection 20 is configured centrally between the two ends of the legs 11, 12 facing away from one another. In such a manner a precise distance is ensured between the solar modules which corresponds to the width of the at least one projection 20 or the distance between, for example, two projections. FIG. 11 additionally shows the threaded holes (reference number 21) already mentioned for additional fixing of the connector 6 in the profile 5 by screws.

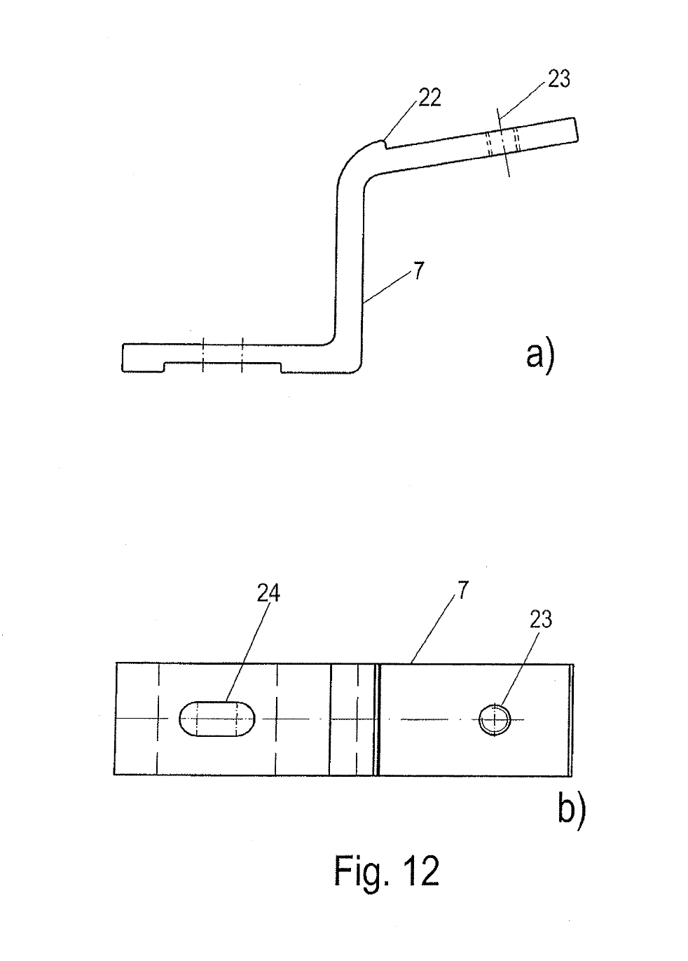

FIG. 12a, b show, respectively, a side view of another connector 7 and a plan view of this connector 7. This connector is also provided with a projection (reference number 22) which delimits the insertion path of the corresponding leg 7c into the chamber 10 of the profile 5 so that in this lower region of the solar module in the mounted state, a defined seat of the solar module or a defined seat of the connector 7 on the solar module is ensured in a simple manner. FIG. 11 also shows threaded holes (reference number 23) or an oblong hole 24, one for additional fixing of the connector 7 in the profile by screwing and one for placing onto pins on the anti-slip devices 4.

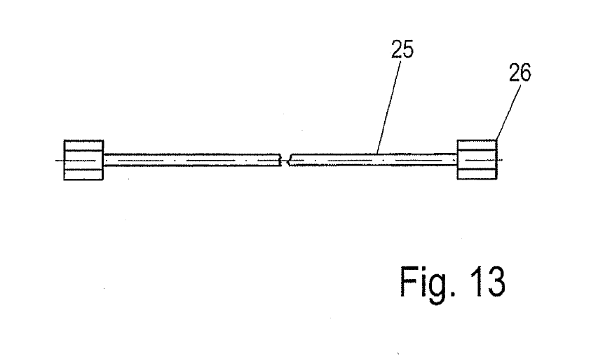

FIG. 13 finally shows a view of the tension element already mentioned, here in the form of a tension cable 25 with fastening elements at the ends facing away from one another for receiving the tensile forces between the profiles 5 or between the connectors 7.

### REFERENCE LIST

1 Solar module (element)
2 Upper edge
3 Lower edge
4 Anti-slip device
Profile
6 Connector
7 Connector with legs 7a, b, c
8 Pin
9 Surface
10 Groove
11 Leg
12 Leg
13 Angle
14 Hole
15 Sheet
16 Compression rod
17 Pin
18 Oblong hole
19 Underside
20 Projection
21 Threaded holes
22 Projection
23 Threaded hole
24 Oblong hole
25 Tension cable
26 Fastening elements

1.-19. (canceled)

20. A module arrangement, comprising:
one or more double module arrangements, each arrangement comprising two solar modules oriented at an angle to one another;
one or more connectors, each connector coupling the two solar modules of each double module arrangement to one another at least in a region of opposing upper edges of the two solar modules;
wherein the one or more connectors comprise two legs arranged at an angle of between 95° and 175°;
one or more profiles arranged under the solar modules, each profile having one or more chambers;
one or more coupling devices having anti-slip devices, each coupling device connecting adjacent double module arrangements to one another; and
wherein the one or more chambers of a respective profile being operatively configured to secure the connector by receiving said connector in said chamber.

21. The module arrangement according to claim 20, further comprising:
one or more further connectors for fixing lower edges of the solar modules, each further connector having a bearing leg and at least one sloping leg arranged at an angle thereto, the further connector being insertable into a respective profile at a lower end of said profile.

22. The module arrangement according to claim 20, wherein the legs of the connector are inserted into corresponding chambers of profiles of two neighboring solar modules at upper edges thereof.

23. The module arrangement according to claim 21, wherein the legs of the connector are inserted into corresponding chambers of profiles of two neighboring solar modules at upper edges thereof.

24. The module arrangement according to claim 20, wherein the anti-slip devices are operatively configured to rest on a subsurface without being mechanically fastened thereto.

25. The module arrangement according to claim 20, wherein two edges from two neighboring double module arrangements are fixed to a respective anti-slip device, one double module arrangement being on one side and the other double module arrangement being on an opposite side of the anti-slip device; and
wherein the anti-slip device interconnects the neighboring double module arrangements via lower edges of the double module arrangements.

26. The module arrangement according to claim 25, wherein the anti-slip device interconnects four double module arrangements via their respective lower edges.

27. The module arrangement according to claim 20, further comprising:
a further connector operatively configured to couple the anti-slip device to a respective double module arrangement.

28. The module arrangement according to claim 25, wherein the anti-slip device is operatively configured such that a distance between lower edges of neighboring double module arrangements is between 50 mm to 500 mm.

29. The module arrangement according to claim 28, wherein the distance is approximately 300 mm.

30. The module arrangement according to claim 25, wherein the anti-slip device is operatively configured such that an intermediate space formed between the neighboring double module arrangements is configured as a walking space.

31. The module arrangement according to claim 20, wherein the anti-slip devices are operatively configured to transfer loads from the double module arrangement into a subsurface.

32. The module arrangement according to claim 20, wherein the anti-slip devices are configured with a floor space on a subsurface that is greater than 200 mm×200 mm.

33. The module arrangement according to claim 32, wherein the floor space is greater than 400 mm×400 mm.

34. The module arrangement according to claim 24, wherein the anti-slip device comprises an adhesive layer that adheres the anti-slip device to a subsurface.

35. The module arrangement according to claim 20, wherein the anti-slip device comprises a lower sheet arrangeable on a subsurface in a mounted position.

36. The module arrangement according to claim 35, wherein the lower sheet comprises a compression member arranged thereon having pins for connecting the anti-slip device to a connector for a lower edge of the solar module.

37. The module arrangement according to claim 35, wherein one-side of the lower sheet has one of a roughened surface and a friction-enhancing coating.

38. The module arrangement according to claim 35, wherein the lower sheet comprises one or more reinforcing elements.

39. The module arrangement according to claim 20, wherein lower edges of each double module arrangement facing away from one another are not interconnected via a supporting strut.

40. The module arrangement according to claim 20, wherein the anti-slip devices comprises protruding pins on which legs of the connectors, which have corresponding holes, are placed.

41. The module arrangement according to claim 20, wherein the profiles have at least one surface on which a respective solar module may rest.

42. The module arrangement according to claim 41, wherein the profiles have an open hollow chamber in which connectors are insertable.
